(19) United States
(12) Patent Application Publication
(10) Pub. No.: US 2025/0285664 A1
(43) Pub. Date: Sep. 11, 2025

(54) INTEGRATED IN-MEMORY COMPUTE CONFIGURED FOR EFFICIENT DATA INPUT AND RESHAPING

(71) Applicant: Rain Neuromorphics Inc., San Francisco, CA (US)

(72) Inventors: Burak Erbagci, San Jose, CA (US); Cagla Cakir, San Francisco, CA (US); Muzaffer Kal, Redmond, WA (US); Alexander Almela Conklin, San Jose, CA (US); Tracey DellaRova, Wake Forest, NC (US)

(21) Appl. No.: 19/033,306

(22) Filed: Jan. 21, 2025

Related U.S. Application Data
(60) Provisional application No. 63/624,483, filed on Jan. 24, 2024.
(60) Provisional application No. 63/624,486, filed on Jan. 24, 2024.

(51) Int. Cl. G11C 7/10; G11C 7/22

(52) U.S. Cl. CPC G11C 7/1084; G11C 7/1036; G11C 7/222

(57) ABSTRACT

A compute engine (CE) is described. The CE includes a compute-in-memory (CIM) module and an input buffer coupled with the CIM module. The CIM module includes storage cells and compute logic coupled with the storage cells. The storage cells are arranged in rows and columns. The input buffer is configured to receive data, reshape the data, and provide reshaped data to the CIM module.

### CROSS REFERENCE TO OTHER APPLICATIONS

This application claims priority to U.S. Provisional Patent Application No. 63/624,483 entitled INTEGRATED IN-MEMORY COMPUTE CONFIGURED FOR EFFICIENT RESHAPING OF INPUT DATA filed Jan. 24, 2024 and U.S. Provisional Patent Application No. 63/624,486 entitled INTEGRATED IN-MEMORY COMPUTE CONFIGURED FOR EFFICIENT DATA INPUT filed Jan. 24, 2024, both of which are incorporated herein by reference for all purposes.

### BACKGROUND OF THE INVENTION

Artificial intelligence (AI), or machine learning, utilizes learning networks loosely inspired by the brain in order to solve problems. Learning networks typically include layers of weights that weight signals (mimicking synapses) combined with activation layers that apply functions to the signals (mimicking neurons). The weight layers are typically interleaved with the activation layers. In the forward, or inference, path, an input signal (e.g. an input vector) is propagated through the learning network. In so doing, a weight layer can be considered to multiply input signals (the input vector, or “activation”, for that weight layer) by the weights (or matrix of weights) stored therein and provide corresponding output signals. For example, the weights may be analog resistances or stored digital values that are multiplied by the input current, voltage or bit signals corresponding to the input vector. The weight layer provides weighted input signals to the next activation layer, if any. Neurons in the activation layer operate on the weighted input signals by applying some activation function (e.g. ReLU or Softmax) and provide output signals corresponding to the statuses of the neurons. The output signals from the activation layer are provided as input signals (i.e. the activation) to the next weight layer, if any. This process may be repeated for the layers of the network, providing output signals that are the resultant of the inference. Learning networks are thus able to reduce complex problems to a set of weights and the applied activation functions. The structure of the network (e.g. the number of and connectivity between layers, the dimensionality of the layers, the type of activation function applied), including the value of the weights, is known as the model.

Although a learning network is capable of solving challenging problems, the computations involved in using such a network are often time consuming. For example, a learning network may use millions of parameters (e.g. weights), which are multiplied by the activations to utilize the learning network. Learning networks can leverage hardware, such as graphics processing units (GPUs) and/or AI accelerators, which perform operations usable in machine learning in parallel. Such tools can improve the speed and efficiency with which data-heavy and other tasks can be accomplished by the learning network.

However, challenges still exist. For example, components of hardware accelerators may have disparate requirements. Different formats for data transfer, data storage, or various operations may be used by different portions of a hardware accelerator. Components having different requirements are desired to function together without unduly sacrificing throughput and latency. Further, power consumption, particularly for edge devices, is desired to be reduced. Consequently, improvements are still desired.

### BRIEF DESCRIPTION OF THE DRAWINGS

Various embodiments of the invention are disclosed in the following detailed description and the accompanying drawings.

FIGS. 1A-1B depict an embodiment of a portion of a compute engine usable in an accelerator for a learning network and a compute tile with which the compute engine may be used.

FIG. 2 depicts an embodiment of a portion of a compute engine usable in an accelerator for a learning network and capable of performing local updates.

FIG. 3 depicts an embodiment of a portion of a compute-in-memory module usable in an accelerator for a learning network.

FIG. 4 depicts an embodiment of a portion of a compute-in-memory module usable in an accelerator for a learning network.

FIG. 5 depicts an embodiment of a portion of a compute engine usable in an accelerator for a learning network and which may reconfigure data.

FIG. 6 depicts an embodiment of a portion of a compute engine usable in an accelerator for a learning network and which may reconfigure data.

FIG. 7 depicts an embodiment of a portion of a compute engine usable in an accelerator for a learning network and which may reconfigure data.

FIG. 8 depicts an embodiment of a timing diagram for a portion of a compute engine usable in an accelerator for a learning network and which may reconfigure data.

FIG. 9 is a flow-chart depicting an embodiment of a method for using a compute engine usable in an accelerator for a learning network and which may reconfigure data.

FIG. 10 is a flow-chart depicting an embodiment of a method for using a compute engine usable in an accelerator for a learning network and which may reconfigure data.

### DETAILED DESCRIPTION

The invention can be implemented in numerous ways, including as a process; an apparatus; a system; a composition of matter; a computer program product embodied on a computer readable storage medium; and/or a processor, such as a processor configured to execute instructions stored on and/or provided by a memory coupled to the processor. In this specification, these implementations, or any other form that the invention may take, may be referred to as techniques. In general, the order of the steps of disclosed processes may be altered within the scope of the invention. Unless stated otherwise, a component such as a processor or a memory described as being configured to perform a task may be implemented as a general component that is temporarily configured to perform the task at a given time or a specific component that is manufactured to perform the task. As used herein, the term ‘processor’ refers to one or more devices, circuits, and/or processing cores configured to process data, such as computer program instructions.

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

A compute engine (CE) is described. The CE includes a compute-in-memory (CIM) module and an input buffer coupled with the CIM module. The CIM module includes storage cells and compute logic coupled with the storage cells. The storage cells are arranged in rows and columns. The input buffer is configured to receive data, reshape the data, and provide reshaped data to the CIM module.

In some embodiments, the input buffer includes shift registers configured to bit-wise transpose the data. The data is bit-parallel and the input buffer bit-serializes the data. A source of the data may be clocked at a first frequency, while the CIM module is clocked at a second frequency. In some embodiments, the input buffer is configured to convert the first frequency to the second frequency. The first frequency may be a multiple of the second frequency. In some embodiments, the input buffer includes at least one. bank and wherein a portion of the data in each of the banks is loaded to the CIM module in parallel.

A compute tile is described. The compute tile includes at least one general-purpose (GP) processor and compute engines (CEs). Each of the CEs includes a compute-in-memory (CIM) module and an input buffer coupled to the CIM module. The CIM module includes storage cells and compute logic coupled with the plurality of storage cells. The storage cells are arranged in a rows and columns. The input buffer is configured to receive data, reshape the data, and provide reshaped data to the CIM module.

In some embodiments, the input buffer includes shift registers configured to bit-wise transpose the data. In some embodiments, the data is bit-parallel and the input buffer bit-serializes the data. A source of the data may be clocked at a first frequency. In such embodiments, the CIM module is clocked at a second frequency. The source of the data may be the GP processor(s). The input buffer is configured to convert the first frequency to the second frequency. The first frequency is a multiple of the second frequency in some embodiments. The input buffer may include at least one bank and wherein a portion of the data in each of the at least one bank is loaded to the CIM module in parallel.

A method is described. The method includes receiving, at an input buffer of a compute engine (CE), data for a compute-in-memory (CIM) module of the CE. The CIM module includes storage cells and compute logic coupled with the storage cells. The storage cells are arranged in rows and columns. The method also includes providing, from the input buffer to the CIM module, reshaped data configured for the CIM module.

In some embodiments, the input buffer includes shift registers. The data is bit-parallel data. The input buffer configured to bit-wise transpose the data. In such embodiments, the receiving further includes loading the bit-parallel data in the plurality of shift registers. Providing the reshaped data further includes providing to the CIM module, from a portion of the shift registers, a portion of the reshaped data such that the reshaped data is bit-serialized.

In some embodiments, a source of the data is clocked at a first frequency. The CIM module is clocked at a second frequency. The input buffer is configured to convert the first frequency to the second frequency. The first frequency may be a multiple of the second frequency. In some embodiments, the input buffer includes at least one bank. Providing the data may further include loading a portion of the data in each of the at least one bank to the CIM module in parallel.

The methods and systems are described in the context of particular features. For example, certain embodiments may highlight particular features. However, the features described herein may be combined in manners not explicitly described. Although described in the context of particular compute engines, CIM hardware modules, storage cells, and logic, other components may be used. For example, although particular embodiments utilize digital SRAM storage cells, other storage cells, including but not limited to analog storage cells (e.g., resistive storage cells) may be used. Similarly, although described in the context of weights and activations, other input vectors (or matrices) and other tensors may be used in conjunction with the methods and systems described herein.

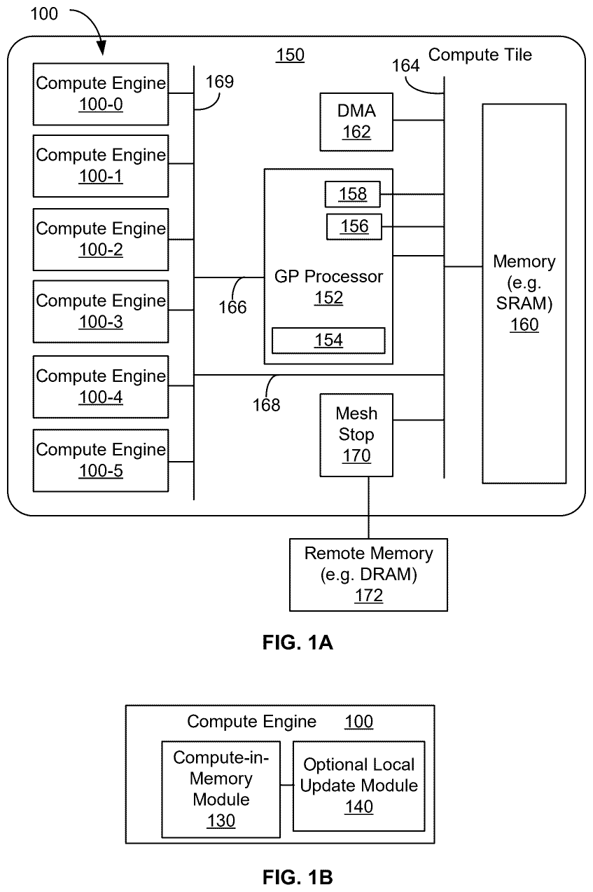

FIGS. 1A-1B depict an embodiment of a portion of compute engine 100 usable in an accelerator for a learning network and compute tile 150 (i.e. an embodiment of the environment) in which the compute engine may be used. FIG. 1A depicts compute tile 150 in which compute engine 100 may be used. FIG. 1B depicts compute engine 100. Compute engine 100 may be part of an AI accelerator that can be deployed for using a model (not explicitly depicted) and, in some embodiments, for allowing for on-chip training of the model (otherwise known as on-chip learning). Referring to FIG. 1A, system 150 is a compute tile and may be considered to be an artificial intelligence (AI) accelerator having an efficient architecture. Compute tile (or simply “tile”) 150 may be implemented as a single integrated circuit. Compute tile 150 includes a general purpose (GP) processor 110 and compute engines 100-0 through 100-5 (collectively or generically compute engines 100) which are analogous to compute engine 100 depicted in FIG. 1A. Also shown are on-tile memory 160 (which may be an SRAM memory) direct memory access (DMA) unit 162, and mesh stop 170. Thus, compute tile 150 may access remote memory 172, which may be DRAM. Remote memory 172 may be used for long term storage. In some embodiments, compute tile 150 may have another configuration. Further, additional or other components may be included on compute tile 150 or some components shown may be omitted. For example, although six compute engines 100 are shown, in other embodiments another number may be included. Similarly, although on-tile memory 160 is shown, in other embodiments, memory 160 may be omitted. GP processor 152 is shown as being coupled with compute engines 100 via compute bus (or other connector) 169 and bus 166. Compute engines 100 are also coupled to bus 164 via bus 168. In other embodiments, GP processor 152 may be connected with compute engines 100 in another manner.

In some embodiments, GP processor 152 is a reduced instruction set computer (RISC) processor. For example, GP processor 152 may be a RISC-V processor or ARM processor. In other embodiments, different and/or additional general purpose processor(s) may be used. The GP processor 152 provides control instructions and, in some embodiments, data to the compute engines 100. GP processor 152 may thus function as part of a control plane for (i.e. providing commands) and is part of the data path for compute engines 100 and tile 150. GP processor 152 may also perform other functions. GP processor 152 may apply activation function(s) to data. For example, an activation function (e.g. a ReLu, Tanh, and/or SoftMax) may be applied to the output of compute engine(s) 100. Thus, GP processor 152 may perform nonlinear operations. GP processor 152 may also perform linear functions and/or other operations. However, GP processor 152 is still desired to have reduced functionality as compared to, for example, a graphics processing unit (GPU) or central processing unit (CPU) of a computer system with which tile 150 might be used.

In some embodiments, GP processor includes an additional fixed function compute block (FFCB) 154 and local memories 156 and 158. In some embodiments, FFCB 154 may be a single instruction multiple data arithmetic logic unit (SIMD ALU). In some embodiments, FFCB 154 may be configured in another manner. FFCB 154 may be a close-coupled fixed-function unit for on-device inference and training of learning networks. In some embodiments, FFCB 154 executes nonlinear operations, number format conversion and/or dynamic scaling. In some embodiments, other and/or additional operations may be performed by FFCB 154. FFCB 154 may be coupled with the data path for the vector processing unit of GP processor 1310. In some embodiments, local memory 156 stores instructions while local memory 158 stores data. GP processor 152 may include other components, such as vector registers, that are not shown for simplicity.

Memory 160 may be or include a static random access memory (SRAM) and/or some other type of memory. Memory 160 may store activations (e.g. input vectors provided to compute tile 150 and the resultant of activation functions applied to the output of compute engines 100). Memory 160 may also store weights. For example, memory 160 may contain a backup copy of the weights or different weights if the weights stored in compute engines 100 are desired to be changed. In some embodiments, memory 160 is organized into banks of cells (e.g. banks of SRAM cells). In such embodiments, specific banks of memory 160 may service specific one(s) of compute engines 100. In other embodiments, banks of memory 160 may service any compute engine 100.

Mesh stop 172 provides an interface between compute tile 150 and the fabric of a mesh network that includes compute tile 150. Thus, mesh stop 172 may be used to communicate with remote DRAM 190. Mesh stop 172 may also be used to communicate with other compute tiles (not shown) with which compute tile 150 may be used. For example, a network on a chip may include multiple compute tiles 150, a GPU or other management processor, and/or other systems which are desired to operate together.

Compute engines 100 are configured to perform, efficiently and in parallel, tasks that may be part of using (e.g. performing inferences) and/or training (e.g. performing inferences and/or updating weights) a model. Compute engines 100 are coupled with and receive commands and, in at least some embodiments, data from GP processor 152. Compute engines 100 are modules which perform vector-matrix multiplications (VMMs) in parallel. Thus, compute engines 100 may perform linear operations. Each compute engine 100 includes a compute-in-memory (CIM) hardware module (shown in FIG. 1A). The CIM hardware module stores weights corresponding to a matrix and is configured to perform a VMM in parallel for the matrix. Compute engines 100 may also include local update (LU) module(s) (shown in FIG. 1A). Such LU module(s) allow compute engines 100 to update weights stored in the CIM. In some embodiments, such LU module(s) may be omitted.

Referring to FIG. 1B, compute engine 100 includes CIM hardware module 130 and optional LU module 140. Although one CIM hardware module 130 and one LU module 140 is shown, a compute engine may include another number of CIM hardware modules 130 and/or another number of LU modules 140. For example, a compute engine might include three CIM hardware modules 130 and one LU module 140, one CIM hardware module 130 and two LU modules 140, or two CIM hardware modules 130 and two LU modules 140.

CIM hardware module 130 is a hardware module that stores data and performs operations. In some embodiments, CIM hardware module 130 stores weights for the model. CIM hardware module 130 also performs operations using the weights. More specifically, CIM hardware module 130 performs vector-matrix multiplications, where the vector may be an input vector provided and the matrix may be weights (i.e. data/parameters) stored by CIM hardware module 130. Thus, CIM hardware module 130 may be considered to include a memory (e.g. that stores the weights) and compute hardware, or compute logic, (e.g. that performs in parallel the vector-matrix multiplication of the stored weights). In some embodiments, the vector may be a matrix (i.e. an n×m vector where n>1 and m>1). For example, CIM hardware module 130 may include an analog static random access memory (SRAM) having multiple SRAM cells and configured to provide output(s) (e.g. voltage(s)) corresponding to the data (weight/parameter) stored in each cell of the SRAM multiplied by a corresponding element of the input vector. In some embodiments CIM hardware module 130 may include a digital static SRAM having multiple SRAM cells and configured to provide output(s) corresponding to the data (weight/parameter) stored in each cell of the digital SRAM multiplied by a corresponding element of the input vector. hardware voltage(s) corresponding to the impedance of each cell multiplied by the corresponding element of the input vector. Other configurations of CIM hardware module 230 are possible. Each CIM hardware module 130 thus stores weights corresponding to a matrix in its cells and is configured to perform a vector-matrix multiplication of the matrix with an input vector.

In order to facilitate on-chip learning, LU module 140 may be provided. LU module 140 is coupled with the corresponding CIM hardware module 130. LU module 140 is used to update the weights (or other data) stored in CIM hardware module 130. LU module 140 is considered local because LU module 140 is in proximity with CIM module 130. For example, LU module 140 may reside on the same integrated circuit as CIM hardware module 130. In some embodiments LU module 140 for a particular compute engine resides in the same integrated circuit as the CIM hardware module 130. In some embodiments, LU module 140 is considered local because it is fabricated on the same substrate (e.g. the same silicon wafer) as the corresponding CIM hardware module 130. In some embodiments, LU module 140 is also used in determining the weight updates. In other embodiments, a separate component may calculate the weight updates. For example, in addition to or in lieu of LU module 140, the weight updates may be determined by a GP processor, in software by other processor(s) not part of compute engine 100 and/or the corresponding AI accelerator, by other hardware that is part of compute engine 100 and/or the corresponding AI accelerator, by other hardware outside of compute engine 100 or the corresponding AI accelerator.

Using compute engine 100 efficiency and performance of a learning network may be improved. Use of CIM hardware modules 130 may dramatically reduce the time to perform the vector-matrix multiplication that provides the weighted signal. Thus, performing inference(s) using compute engine 100 may require less time and power. This may improve efficiency of training and use of the model. LU modules 140 allow for local updates to the weights in CIM hardware modules 130. This may reduce the data movement that may otherwise be required for weight updates. Consequently, the time taken for training may be greatly reduced. In some embodiments, the time taken for a weight update using LU modules 140 may be an order of magnitude less (i.e. require one-tenth the time) than if updates are not performed locally. Efficiency and performance of a learning network provided using system 100 may be increased.

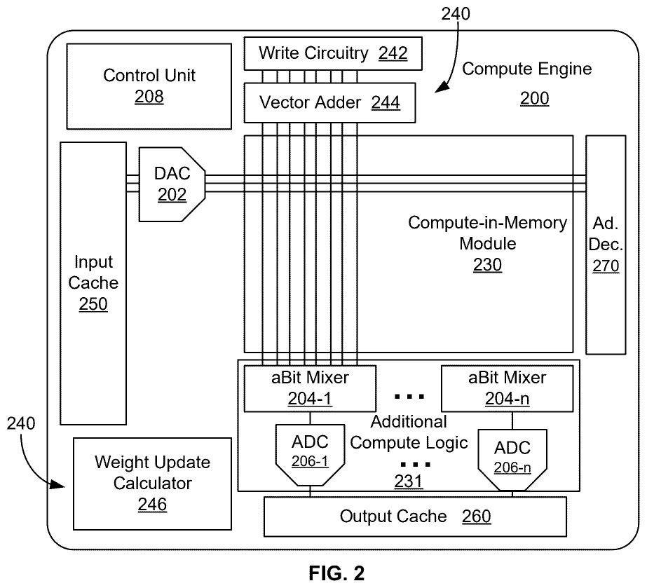

FIG. 2 depicts an embodiment of compute engine 200 usable in an AI accelerator and that may be capable of performing local updates. Compute engine 200 may be a hardware compute engine analogous to compute engine 100. Compute engine 200 thus includes CIM hardware module 230 and optional LU module 240 analogous to CIM hardware modules 130 and LU modules 140, respectively. Compute engine 200 includes input cache 250 (also termed an input buffer 250), output cache 260, and address decoder 270. Additional compute logic 231 is also shown. In some embodiments, additional compute logic 231 includes analog bit mixer (aBit mixer) 204-1 through 204-n (generically or collectively 204), and analog to digital converter(s) (ADC(s)) 206-1 through 206-n (generically or collectively 206). However, for a fully digital CIM hardware module 230, additional compute logic 231 may include logic such as adder trees and accumulators. In some embodiments, such logic may simply be included as part of CIM hardware module 230. In some embodiments, therefore, the output of CIM hardware module 230 may be provided to output cache 260. Although particular numbers of components 202, 204, 206, 230, 231, 240, 242, 244, 246, 260, and 270 are shown, another number of one or more components 202, 204, 206, 230, 231, 240, 242, 244, 246, 160, and 270 may be present. Further, in some embodiments, particular components may be omitted or replaced. For example, DAC 202, analog bit mixer 204, and ADC 206 may be present only for analog weights.

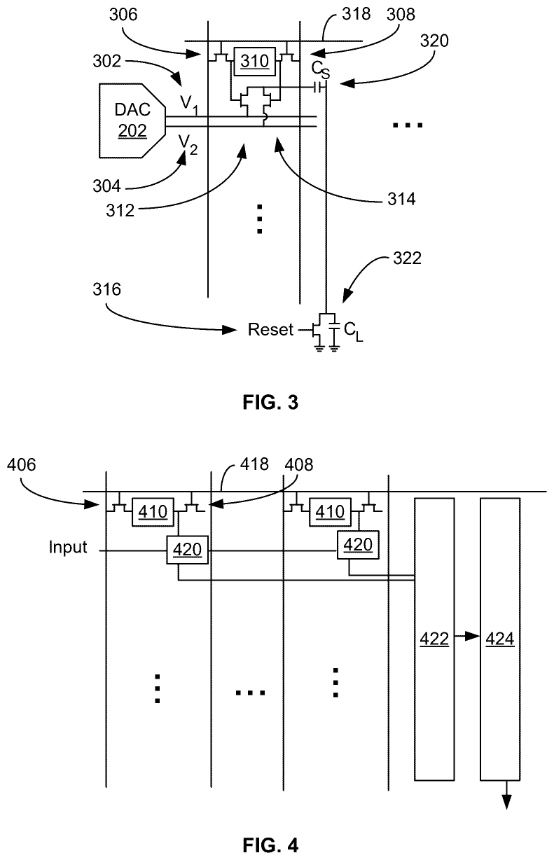

CIM hardware module 230 is a hardware module that stores data corresponding to weights and performs vector-matrix multiplications. The vector is an input vector provided to CIM hardware module 230 (e.g. via input cache 250) and the matrix includes the weights stored by CIM hardware module 230. In some embodiments, the vector may be a matrix. Examples of embodiments CIM modules that may be used in CIM hardware module 230 are depicted in FIGS. 3 and 4.

FIG. 3 depicts an embodiment of a cell in one embodiment of an SRAM CIM module usable for CIM hardware module 230. Also shown is DAC 202 of compute engine 200. For clarity, only one SRAM cell 310 is shown. However, multiple SRAM cells 310 may be present. For example, multiple SRAM cells 310 may be arranged in a rectangular array. An SRAM cell 310 may store a weight or a part of the weight. The CIM hardware module shown includes lines 302, 304, and 318, transistors 306, 308, 312, 314, and 316, capacitors 320 (C_{S}) and 322 (C_{L}). In the embodiment shown in FIG. 3, DAC 202 converts a digital input voltage to differential voltages, V1 and V2, with zero reference. These voltages are coupled to each cell within the row. DAC 202 is thus used to temporal code differentially. Lines 302 and 304 carry voltages V1 and V2, respectively, from DAC 202. Line 318 is coupled with address decoder 270 (not shown in FIG. 3) and used to select cell 310 (and, in the embodiment shown, the entire row including cell 310), via transistors 306 and 308.

In operation, voltages of capacitors 320 and 322 are set to zero, for example via Reset provided to transistor 316. DAC 202 provides the differential voltages on lines 302 and 304, and the address decoder (not shown in FIG. 3) selects the row of cell 310 via line 318. Transistor 312 passes input voltage V1 if SRAM cell 310 stores a logical 1, while transistor 314 passes input voltage V2 if SRAM cell 310 stores a zero. Consequently, capacitor 320 is provided with the appropriate voltage based on the contents of SRAM cell 310. Capacitor 320 is in series with capacitor 322. Thus, capacitors 320 and 322 act as capacitive voltage divider. Each row in the column of SRAM cell 310 contributes to the total voltage corresponding to the voltage passed, the capacitance, C_{S}, of capacitor 320, and the capacitance, C_{L}, of capacitor 322. Each row contributes a corresponding voltage to the capacitor 322. The output voltage is measured across capacitor 322. In some embodiments, this voltage is passed to the corresponding aBit mixer 204 for the column. In some embodiments, capacitors 320 and 322 may be replaced by transistors to act as resistors, creating a resistive voltage divider instead of the capacitive voltage divider. Thus, using the configuration depicted in FIG. 3, CIM hardware module 230 may perform a vector-matrix multiplication using data stored in SRAM cells 310.

FIG. 4 depicts an embodiment of a cell in one embodiment of a digital SRAM module usable for CIM hardware module 230. For clarity, only one digital SRAM cell 410 is labeled. However, multiple cells 410 are present and may be arranged in a rectangular array. Also labeled are corresponding transistors 406 and 408 for each cell, line 418, logic gates 420, adder tree 422 and accumulator 424.

In operation, a row including digital SRAM cell 410 is enabled by address decoder 270 (not shown in FIG. 4) using line 418. Transistors 406 and 408 are enabled, allowing the data stored in digital SRAM cell 410 to be provided to logic gates 420. Logic gates 420 combine the data stored in digital SRAM cell 410 with the input vector. Thus, the binary weights stored in digital SRAM cells 410 are combined with (e.g. multiplied by) the binary inputs. Thus, the multiplication performed may be a bit serial multiplication. The output of logic gates 420 are added using adder tree 422 and combined by accumulator 424. Thus, using the configuration depicted in FIG. 4, CIM hardware module 230 may perform a vector-matrix multiplication using data stored in digital SRAM cells 410.

Referring back to FIG. 2, CIM hardware module 230 thus stores weights corresponding to a matrix in its cells and is configured to perform a vector-matrix multiplication of the matrix with an input vector. In some embodiments, compute engine 200 stores positive weights in CIM hardware module 230. However, the use of both positive and negative weights may be desired for some models and/or some applications. In such cases, the sign may be accounted for by a sign bit or other mapping of the sign to CIM hardware module 230.

Input cache 250 receives an input vector for which a vector-matrix multiplication is desired to be performed. The input vector may be read from a memory, from a cache or register in the processor, or obtained in another manner. For analog cells, such as depicted in FIG. 3, digital-to-analog converter (DAC) 202 may convert a digital input vector to analog in order for CIM hardware module 230 to operate on the vector. Although shown as connected to only some portions of CIM hardware module 230, DAC 202 may be connected to all of the cells of CIM hardware module 230. Alternatively, multiple DACs 202 may be used to connect to all cells of CIM hardware module 230. Address decoder 270 includes address circuitry configured to selectively couple vector adder 244 and write circuitry 242 with each cell of CIM hardware module 230. Address decoder 270 selects the cells in CIM hardware module 230. For example, address decoder 270 may select individual cells, rows, or columns to be updated, undergo a vector-matrix multiplication, or output the results. In some embodiments, aBit mixer 204 combines the results from CIM hardware module 230. Use of aBit mixer 204 may save on ADCs 206 and allows access to analog output voltages. ADC(s) 206 convert the analog resultant of the vector-matrix multiplication to digital form. Output cache 260 receives the result of the vector-matrix multiplication and outputs the result from compute engine 200. Thus, a vector-matrix multiplication may be performed using CIM hardware module 230 and cells 310.

For a digital SRAM CIM module, input cache 250 may serialize an input vector. The input vector is provided to CIM hardware module 230. As previously indicated, DAC 202 may be omitted for a digital CIM hardware module 230, for example which uses digital SRAM storage cells 410. Logic gates 420 combine (e.g., multiply) the bits from the input vector with the bits stored in SRAM cells 410. The output is provided to adder trees 422 and to accumulator 424. In some embodiments, therefore, adder trees 422 and accumulator 424 may be considered to be part of CIM hardware module 230. The resultant is provided to output cache 260. Thus, a digital vector-matrix multiplication may be performed in parallel using CIM hardware module 230.

LU module 240 includes write circuitry 242 and vector adder 244. In some embodiments, LU module 240 includes weight update calculator 246. In other embodiments, weight update calculator 246 may be a separate component and/or may not reside within compute engine 200. Weigh update calculator 246 is used to determine how to update to the weights stored in CIM hardware module 230. In some embodiments, the updates are determined sequentially based upon target outputs for the learning system of which compute engine 200 is a part. In some embodiments, the weight update provided may be sign-based (e.g. increments for a positive sign in the gradient of the loss function and decrements for a negative sign in the gradient of the loss function). In some embodiments, the weight update may be ternary (e.g. increments for a positive sign in the gradient of the loss function, decrements for a negative sign in the gradient of the loss function, and leaves the weight unchanged for a zero gradient of the loss function). Other types of weight updates may be possible. In some embodiments, weight update calculator 246 provides an update signal indicating how each weight is to be updated. The weight stored in a cell of CIM hardware module 230 is sensed and is increased, decreased, or left unchanged based on the update signal. In particular, the weight update may be provided to vector adder 244, which also reads the weight of a cell in CIM hardware module 230. More specifically, adder 244 is configured to be selectively coupled with each cell of CIM hardware module by address decoder 270. Vector adder 244 receives a weight update and adds the weight update with a weight for each cell. Thus, the sum of the weight update and the weight is determined. The resulting sum (i.e. the updated weight) is provided to write circuitry 242. Write circuitry 242 is coupled with vector adder 244 and the cells of CIM hardware module 230. Write circuitry 242 writes the sum of the weight and the weight update to each cell. In some embodiments, LU module 240 further includes a local batched weight update calculator (not shown in FIG. 2) coupled with vector adder 244. Such a batched weight update calculator is configured to determine the weight update.

Compute engine 200 may also include control unit 208. Control unit 208 generates the control signals depending on the operation mode of compute engine 200. Control unit 240 is configured to provide control signals to CIM hardware module 230 and LU module 1549. Some of the control signals correspond to an inference mode. Some of the control signals correspond to a training, or weight update mode. In some embodiments, the mode is controlled by a control processor (not shown in FIG. 2, but analogous to processor 110) that generates control signals based on the Instruction Set Architecture (ISA).

Using compute engine 200, efficiency and performance of a learning network may be improved. CIM hardware module 230 may dramatically reduce the time to perform the vector-matrix multiplication. Thus, performing inference(s) using compute engine 200 may require less time and power. This may improve efficiency of training and use of the model. LU module 240 may perform local updates to the weights stored in the cells of CIM hardware module 230. This may reduce the data movement that may otherwise be required for weight updates. Consequently, the time taken for training may be dramatically reduced. Efficiency and performance of a learning network provided using compute engine 200 may be increased.

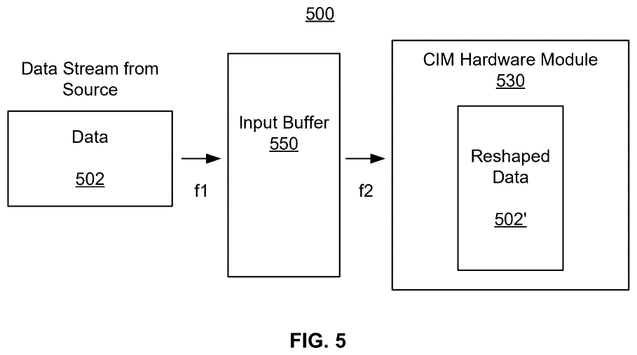

FIG. 5 depicts an embodiment of a portion of compute engine 500 usable in an accelerator for a learning network and which may reconfigure data. For example, compute engine 500 may reshape data and/or change the speed at which data is transferred to CIM hardware module 530. Compute engine 500 is analogous to compute engines 100 and/or 200. Compute 500 includes CIM hardware module 530 and input buffer 550 that are analogous to CIM hardware modules 130 and 230 and input cache 250. For clarity, other components which may be present, such as address decoder 270, are not shown.

CIM hardware module 530 includes storage cells and compute logic. For example, CIM hardware module 530 may include storage cells that are analogous to storage cells 410. The storage cells of CIM hardware module 530 may be organized into an array. The array may include a particular number of storage cells for each weight. For example, if 4-bit weights are stored in CIM hardware module 530, then storage cells in four columns of a single row store a weight. If 8-bit weights are stored in CIM hardware module 530, then eight columns of a row in the array of storage cells store the weight. Consequently, multiple columns may store a single weight, but each row corresponds to a different weight for CIM hardware module 530.

The compute logic for CIM hardware module 530 includes logic gates analogous to logic gates 420, adder tree(s) (not shown), and accumulator(s) (not shown). The logic gates are coupled with the storage cells and perform a bit wise multiplication of the data in the corresponding storage cell and the input vector. For example, each logic gate(s) may include a NOR gate that receives the inverted output of the data in corresponding storage cell 510 and the inverted bit of the input vector. Although described in the context of a digital CIM module, nothing prevents CIM module 530 from being configured for analog storage, for example storage of weights in resistive cells or other analogous cells.

Input buffer 550 is analogous to input buffer 250. Thus, input buffer 550 receives data to be provided to CIM hardware module 530, temporarily stores the data, and provides the data to CIM hardware module 530. For example, input buffer 550 may receive input vector data (i.e., data for an activation) from GP processor 152, memory 160, DRAM 172, or another compute tile. The input vector is desired to be provided to CIM hardware module 530 to perform a VMM with stored weights. In some embodiments, input buffer 550 may receive weight data to be stored in storage cells of CIM hardware module 530. Some portion of the data received by input buffer 550 is depicted in FIG. 5 as data 502. The data received by input buffer 550 may have a particular configuration, or format, based upon the source of the data and/or the type of data transfer used. Further, the speed at which input buffer 550 receives data 502 may depend upon the source and/or the transfer used. For example, data 502 may be provided to input buffer 550 based on a clock having a frequency of f1. Similarly, data 502 may be provided to input buffer 550 in a bit-parallel.

Although input buffer 550 may receive data 502, CIM module 530 may be configured for a different type of data transfer or data having a different configuration than data 502 provided to input buffer 550. For example, CIM hardware module 530 may accept data based upon an internal clock having a frequency f2 that differs from f1. In some embodiments, the clock speed used for loading data to CIM hardware module 530 may be lower than that of the data transfer. In other words, f2<f1. In some cases, f1 is a multiple of f2. Similarly, CIM hardware module 530 may expect bit serialized data, while data 502 is transferred in bit-parallel. CIM hardware module 530 may also store data words (e.g. weights) across multiple columns of a row. Similarly, data for an element of an input vector (an element of an activation) is desired to be provided along a row. For example, a 4-bit element of an input vector may be desired to be multiplied by a 4-bit weight that is stored in a row. As a result, the bits of the element of the input vector are to be provided to the row storing the weights. In the absence of input buffer 550, these differences may be challenging to accommodate.

Input buffer 550 may be utilized to reshape and/or change the speed at which data 502 is provided to CIM hardware module 530. For example, input buffer 550 transfers information to CIM hardware module 530 such that data 502 is transformed (or reshaped) to reshaped data 502′. In some embodiments, this is accomplished by input buffer 550 receiving data 502 in rows, storing data 502 in internal storage (not shown) in a configuration that facilitates reshaping of the data, and outputting information to CIM hardware module 530 such that reshaped data 530 is loaded column-by-column. Input buffer 550 may serialize bit-parallel data 502 to provide data in the appropriate format to CIM hardware module 530. For example, input buffer 550 may ensure that bits for an element of an input vector to be multiplied by a weight are transferred to multiple columns of a row. Compute engine 500 may also account for differences in speed of the data transfer to input buffer 550 from the speed of data transfer from input buffer 550 to CIM hardware module 530. For example, input buffer 550 may receive data 502 at frequency f1. Because input buffer 550 may temporarily store the data, input buffer 550 may load data to CIM hardware module 530 at a different clock speed.

Thus, input buffer 550 may facilitate operation of compute engine 500. For example, input buffer 550 may account for different transfer speeds to compute engine 500 (i.e. to input buffer 550 at frequency f1) and within compute engine 500 (i.e. from input buffer 550 to CIM hardware module 530 at frequency f2). Similarly, input buffer 550 may change the manner in which data is transferred. For example, bit-parallel data may be provided to input buffer 550, and thus compute engine 500. Bit serial data may be provided to CIM hardware module 530 from input buffer 550. In addition, input buffer 550 may reshape data. For example, data input to rows of input buffer 550 may be output to columns of CIM hardware module 530. As a result, data 502 for input vectors may be provided to the appropriate rows and columns of CIM hardware module 530 as data 502′. Consequently, CIM hardware module 530 may perform VMMs as desired. Thus, the compute tile and learning network incorporating compute engine 500 may have improved performance.

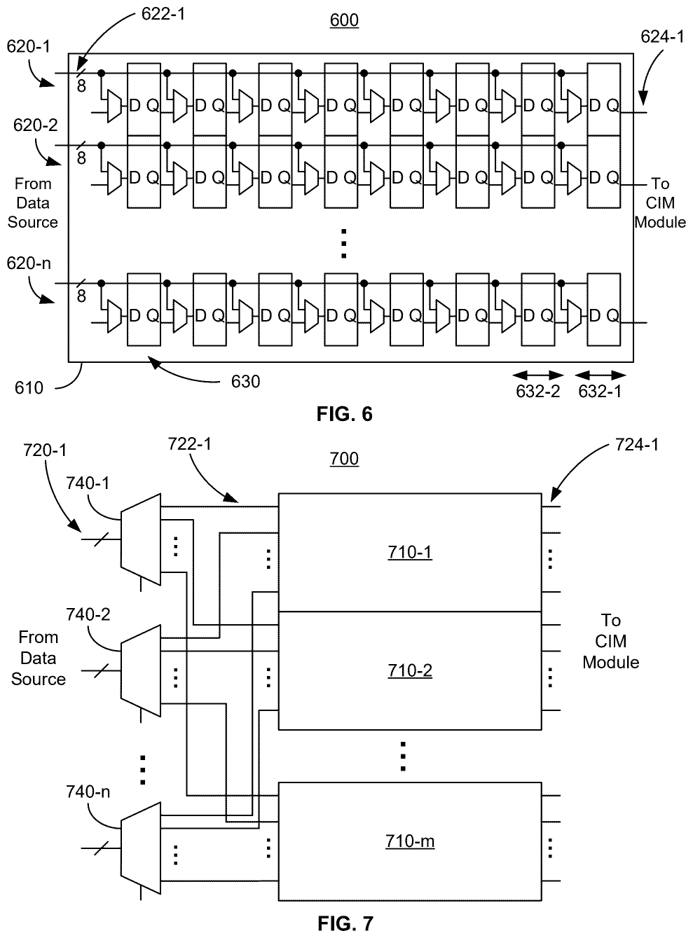

FIG. 6 depicts an embodiment of a portion of an input buffer 600 usable in an accelerator for a learning network and which may reconfigure data. For example, input buffer 600 may reshape data and/or change the speed at which data is transferred from a data source to a CIM hardware module (not shown). Input buffer 600 is analogous to input buffer 250 and/or input buffer 550. In the embodiment shown, input buffer 600 includes bank 610. Bank 610 includes shift registers 620-1 through 620-n, each including a row of eight registers 630 (only one of which is labeled). In the embodiment shown, a data word of the data source includes eight bits. Other numbers of registers 630 and other sizes of data word may be used. In some embodiments, bank 610 is one of a plurality of banks of input buffer 600. For clarity, other components which may be present are not shown.

Bank 610 is configured to receive information from the data source in bit-parallel and output information to the CIM hardware module bit-serially. For example, bank 610 may receive n data words of the data (8n bits) in parallel within one clock cycle of the data source. Shift register 620-1 receives a first data word of the data via lines 622-1, and each bit of the first data word is stored in a register 630 of shift register 620-1. Other shift registers 620 receive and store data words in a manner analogous to shift register 620-1. Bank 610 may be configured to store the data such that columns 632 (only two of which are labeled) of registers 630 correspond to bit-significance of data words of the stored data. In the example shown, rightmost column 632-1 corresponds to the most significant bit of the data words, second-rightmost column 632-2 corresponds to the second-most significant bit, etc. Other configurations of storage may be used. For example, rightmost column 632-1 may correspond to the least significant bit of the data words, second-rightmost column 632-2 corresponds to the next-least significant bit, etc.

The data of rightmost column 632-1 of registers 630 is provided to the CIM hardware module via lines 624 (only one of which, lines 624-1, is labeled). The shift registers 620 may be clocked at a frequency equal to that of the CIM hardware module (e.g., frequency f2 in FIG. 5) to shift the bits stored in registers 630 one column rightward. Thus, in the example shown, a stored bit of each shift register 620 is provided to a column of the CIM hardware module each clock cycle, ordered from most significant to least significant. Thus, data provided to rows 620 of shift registers 630 may be output in columns to the CIM hardware module.

Input buffer 600 may thus account for different transfer speeds from the data source and to the CIM hardware module. Bit-parallel data may be received via 622 and provided bit serially via lines 624. Data provided to rows 620 of shift register 600 may be output to columns of the CIM hardware module. Consequently, the CIM hardware module may perform VMMs as desired. Thus, the compute tile and learning network incorporating input buffer 600 may have improved performance.

FIG. 7 depicts an embodiment of a portion of an input buffer 700 usable in an accelerator for a learning network and which may reconfigure data. For example, input buffer 700 may reshape data and/or change the speed at which data is transferred from a data source to a CIM hardware module (not shown). Input buffer 700 is analogous to input buffer 250 and/or input buffers 550 and 600. In the embodiment shown, input buffer 700 includes banks 710, analogous to bank 610, and demultiplexers 740. For clarity, other components which may be present are not shown.

Input buffer 700 is configured to receive information from the data source in bit-parallel and store it in banks 710. The data source may transfer n data words of the data in parallel via 720 (only one of which, 720-1, is labeled). Multiplexers 740 route the n data words to a bank 710. For example, the n data words may be routed to bank 710-1. A first data word is routed to bank 710-1 through 722-1 by demultiplexer 740-1, a second data word is routed to bank 710-1 by demultiplexer 740-2, etc. Other banks 710 receive and store data words in a manner analogous to bank 710-1. Thus, a total of m times n data words may be stored in input buffer 700. Various configurations of storage may be used. For example, the most significant bit of each of the m times n data words may be stored in a rightmost column of registers of banks 710. The data is provided serially to the CIM module via 724 (only one of which, 724-1, is labeled). In some embodiments, a portion of the data in each of banks 710 is loaded to the CIM module in parallel. For example, a bit from each of the m times n data words may be provided to the CIM module each clock cycle, ordered from most significant to least significant.

Input buffer 700 may thus account for different transfer speeds from the data source and to the CIM module. Bit-parallel data may be received via 720 and provided bit serially to a row via 724. Further, data stored in rows of banks 710 may be provided to columns of the CIM hardware module. Consequently, the CIM hardware module may perform VMMs as desired. Thus, the compute tile and learning network incorporating input buffer 700 may have improved performance.

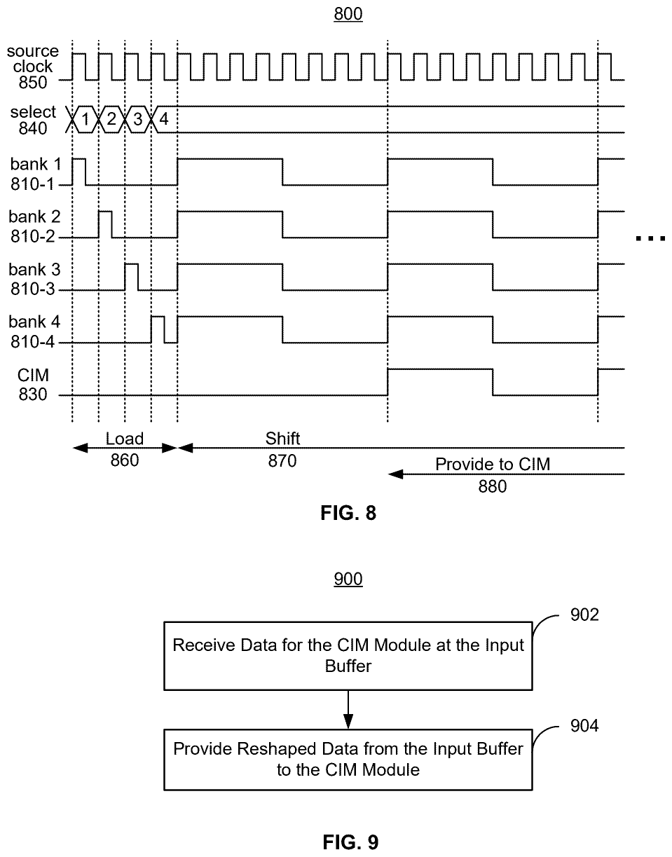

FIG. 8 depicts an embodiment of a timing diagram of reshaping data using an input buffer. The input buffer provides the data to a CIM module. Diagram 800 is described in the context of an embodiment of input buffer 700 with four banks 710 (i.e., m=4). However, the diagram may depict operation of other input caches, input buffers, etc.

Source clock signal 850 is matched to or provided by a clock of a data source. During loading 860, select signal 840 selects a bank of banks 710 to route the data source to. Select signal 840 is provided to select lines (not labeled) of demultiplexers 740. As select signal 840 iterates from one to four over four cycles of source clock signal 850, bank signals 810-1 through 810-4 are activated to store the data being routed by demultiplexers 740 into each of banks 710.

During shift 870 and provide to CIM 880, bank signals 810 and CIM signal 830 are matched to or provided by a clock of the CIM module. Matching may be performed by a counter, clock divider, clock multiplier, finite state machine, etc. For example, in the embodiment shown, source clock signal 850 is a multiple of (eight times) the clock frequency of the CIM module. Matching may be performed using an at least three-bit counter applied to source clock signal 850. Although bank signals 810 and CIM signal 830 show a 50% duty cycle during loading 860, shifting 870, and providing to CIM 880, duty cycle may vary (e.g., from a 50% duty cycle during loading 860 to a 6.25% duty cycle during shifting). Bank signals 810 shift the data in banks 710 during shifting 870. CIM signal 830 stores the output of banks 710 in the CIM during providing to CIM 880. Thus, a bit from each of the m times n data words may be provided to the CIM module each cycle of the clock of the CIM module. Various configurations of storage may be used. For example, the most significant bit of each word of the data may be stored in a rightmost column of registers of banks 710. The data may then be provided bit-serially to the CIM module, ordered from most significant bit to least significant bit.

The input buffer depicted in timing diagram 800 may thus account for different transfer speeds from the data source and to the CIM module. Bit-parallel data may be received during loading 860 and provided bit serially during providing to CIM 880. Consequently, the CIM module may perform VMMs as desired. Thus, the compute tile and learning network incorporating the input buffer depicted in timing diagram 800 may have improved performance.

FIG. 9 is a flow chart depicting an embodiment of a method 900 for reshaping data using an input buffer. Method 900 is described in the context of compute engine 500. However, method 900 is usable with other compute engines and/or compute tiles. Although particular processes are shown in an order, the processes may be performed in another order, including in parallel. Further, processes may have substeps.

Data is received at an input buffer of a compute engine, at 902. The data received may have a particular configuration. For example, the data may be received in bit-parallel form. However, the CIM module of the compute engine may expect serialized data and/or may desire data to be provided in a different order. At 904, the input buffer reshapes the data and provides the reshaped data to the CIM hardware module. For example, at 902, input buffer 550 may receive data. This data may be temporarily stored in input buffer 550. At 904, the data is provided to CIM hardware module 530. Input buffer 550 may serialize bit-parallel data 502 to provide data in the appropriate format to CIM hardware module 530. Because it is temporarily stored by input buffer 550, input bovver 550 may also account for differences in speed of the data transfer to input buffer 550 from the speed of data transfer from input buffer 550 to CIM hardware module 530. For example, input buffer 550 may receive data 502 at frequency f1. Because input buffer 550 may temporarily store the data, input buffer 550 may load data to CIM hardware module 530 at a different clock speed.

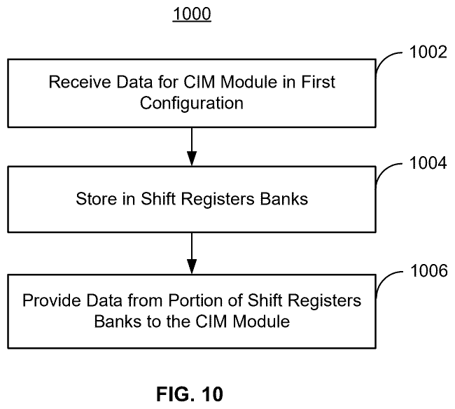

FIG. 10 is a flow-chart depicting an embodiment of method 1000 for using a compute engine usable in an accelerator for a learning network and which may reconfigure data. Method 1000 is described in the context of input buffer 600. However, method 1000 is usable with other compute engines and/or compute tiles. Although particular processes are shown in an order, the processes may be performed in another order, including in parallel. Further, processes may have substeps.

Data is received by the input buffer, at 1002. The data received is in a first configuration, or format. In some embodiments, data may be received at one or more banks of the input buffer. At 1004, the data is stored in shift registers of the bank(s) of the input buffer. In some embodiments, storage in shift registers facilitates the reshaping of the data. The data is then provided from a portion of the banks to the CIM hardware module, at 1006. Thus, the data output from the input buffer may be reshaped. For example, data received in rows of the input buffer may be output to columns of the CIM hardware module. Further, storage in the banks allows for the speed at which data is provided form the input buffer to the CIM hardware module to be at least somewhat decoupled from the speed at which data is provided to the input buffer.

For example, at 1002, data is received at input buffer 600. For example lines 622 may provide multiple bits of data to input buffer 600. Where multiple banks are present, demultiplexers, such as demultiplexers 740, route the data to the appropriate bank. At 1004, the data is stored in banks, such as bank 610 of input buffer 600. The data received over lines 622 is loaded into a row of shift registers 630. Thus, at 1004, data is loaded into the rows 620 of shift registers 630 in bank 610. This may be repeated for multiple banks, such as banks 710. At 1006, the data is output by a portion of the bank(s) 610 to the CIM module in the appropriate format. For example, the data of rightmost column 632-1 of registers 630 is provided to the CIM module via lines 624. At 1006, the shift registers 620 may be clocked at a frequency equal to that of the CIM module (e.g., frequency f2 in FIG. 5) to shift the bits stored in registers 630 one column rightward and provide the data to the CIM hardware module at the appropriate speed.

Thus, using method 1000, data may be input to input buffer 600 in bit-parallel, and output to rows of the CIM hardware module in bit-serial format. Further, data is loaded into rows of input buffer 600 and output to columns of the CIM hardware module. Thus, input buffer 600 reshapes the data as part of method 1000. Further, clocking of registers 630 at 1006 allows the speed at which data is provided to the CIM hardware module to differ form the speed at which data is provided to input buffer 600 at 1002. Thus, method 1000 not only allows for reshaping of data, but also for the speeds at which data are presented to the input buffer to be decoupled from the speed at which data is provided to the CIM hardware module. As such, differences in components in the compute tile may be accounted for and performance of the compute engine, compute tile, and learning network to be improved.

Although the foregoing embodiments have been described in some detail for purposes of clarity of understanding, the invention is not limited to the details provided. There are many alternative ways of implementing the invention. The disclosed embodiments are illustrative and not restrictive.

What is claimed is:

1. A compute engine (CE), comprising:
a compute-in-memory (CIM) module including a plurality of storage cells and compute logic coupled with the plurality of storage cells, the plurality of storage cells being arranged in a plurality of rows and a plurality of columns; and
an input buffer coupled with the CIM module and configured to receive data, reshape the data, and provide reshaped data to the CIM module.

2. The CE of claim 1, wherein the input buffer includes a plurality of shift registers configured to bit-wise transpose the data.

3. The CE of claim 1, wherein the data is bit-parallel and the input buffer bit-serializes the data.

4. The CE of claim 1, wherein a source of the data is clocked at a first frequency and the CIM module is clocked at a second frequency.

5. The CE of claim 4, wherein the input buffer is configured to convert the first frequency to the second frequency.

6. The CE of claim 4, wherein the first frequency is a multiple of the second frequency.

7. The CE of claim 1, wherein the input buffer includes at least one bank and wherein a portion of the data in each of the at least one bank is loaded to the CIM module in parallel.

8. The CE of claim 7, further comprising:
a demultiplexer configured to route a portion of the data to a bank of the at least one bank.

9. A compute tile, comprising:
at least one general-purpose (GP) processor; and
a plurality of compute engines (CEs), each of the plurality of CEs including a compute-in-memory (CIM) module and an input buffer coupled to the CIM module, the CIM module including a plurality of storage cells and compute logic coupled with the plurality of storage cells, the plurality of storage cells being arranged in a plurality of rows and a plurality of columns, the an input buffer being configured to receive data, reshape the data, and provide reshaped data to the CIM module.

10. The compute tile of claim 9, wherein the input buffer includes a plurality of shift registers configured to bit-wise transpose the data.

11. The compute tile of claim 9, wherein the data is bit-parallel and the input buffer bit-serializes the data.

12. The compute tile of claim 9, wherein a source of the data is clocked at a first frequency and the CIM module is clocked at a second frequency.

13. The compute tile of claim 12, wherein the source of the data is the at least one GP processor.

14. The compute tile of claim 12, wherein the input buffer is configured to convert the first frequency to the second frequency.

15. The compute tile of claim 12, wherein the first frequency is a multiple of the second frequency.

16. The compute tile of claim 9, wherein the input buffer includes at least one bank and wherein a portion of the data in each of the at least one bank is loaded to the CIM module in parallel.

17. A method, comprising:
receiving, at an input buffer of a compute engine (CE), data for a compute-in-memory (CIM) module of the CE, the CIM module including a plurality of storage cells and compute logic coupled with the plurality of storage cells, the plurality of storage cells being arranged in a plurality of rows and a plurality of columns; and
providing, from the input buffer to the CIM module, reshaped data configured for the CIM module.

18. The method of claim 17, wherein the input buffer includes a plurality of shift registers, wherein the data is bit-parallel data, wherein the input buffer configured to bit-wise transpose the data, wherein the receiving further includes:
loading the bit-parallel data in the plurality of shift registers; and wherein the providing the reshaped data further includes
providing to the CIM module, from a portion of the plurality of shift registers, a portion of the reshaped data such that the reshaped data is bit-serialized.

19. The method of claim 17, wherein a source of the data is clocked at a first frequency, wherein the CIM module is clocked at a second frequency, the input buffer is configured to convert the first frequency to the second frequency, the first frequency being a multiple of the second frequency.

20. The method of claim 17, wherein the input buffer includes at least one bank and wherein the providing further includes:
loading a portion of the data in each of the at least one bank to the CIM module in parallel.
